(19) United States
(12) Patent Application Publication
(10) Pub. No.: US 2025/0287711 A1
(43) Pub. Date: Sep. 11, 2025

(54) Embedded metasurface

(71) Applicant: APPLE INC., Cupertino, CA (US)

(72) Inventors: Keith Lyon, San Jose, CA (US); Gershon Rosenblum, Newark, CA (US)

(21) Appl. No.: 19/049,022

(22) Filed: Feb. 10, 2025

Related U.S. Application Data
(60) Provisional application No. 63/561,337, filed on Mar. 5, 2024.

(51) Int. Cl. H10F 39/00; H10F 39/18; H10F 39/95

(52) U.S. Cl. CPC H10F 39/806; H10F 39/018; H10F 39/024; H10F 39/182; H10F 39/1843; H10F 39/809; H10F 39/811; H10F 39/95

(57) ABSTRACT

A sensing device includes a first die, having a front and a back side, defining a first array of first sensor elements outputting first electrical signals in response to optical radiation that is incident on the front side of the first die in a first band of wavelengths. A second die has a first side fixedly aligned with the first die back side and defines a second array of second sensor elements that output second electrical signals in response to the optical radiation in a second band of wavelengths, different from the first band, which passes through the first die and is incident on the second die first side. An optical metasurface is disposed between the first and second dies and directs the optical radiation in the second band of wavelengths onto the second sensor elements. Readout circuitry reads the first and second electrical signals out of the device.

### CROSS-REFERENCE TO RELATED APPLICATION

This application claims the benefit of U.S. Provisional Patent Application 63/561,337 filed Mar. 5, 2024, which is incorporated herein by reference.

### FIELD OF THE INVENTION

This invention relates generally to optoelectronic devices, and specifically to image sensors and methods for their fabrication.

### BACKGROUND OF THE INVENTION

U.S. patent application Ser. No. 17/903,067, which is incorporated herein by reference, describes a stacked image sensor. In an upper stack the sensor comprises an array of red, green, and blue (RGB) sensors or pixels, and in a lower stack the sensor comprises an array of infra-red (IR) sensors or pixels. The IR radiation for the lower IR pixels passes through the RGB pixels, so that elements of the RGB pixels may be constructed from material transparent to IR, e.g., silicon or poly-silicon.

### SUMMARY OF THE INVENTION

An embodiment of the present invention provides a multispectral sensing device, consisting of:
a first die, which has a front side and a back side and is patterned to define a first array of first sensor elements configured to output first electrical signals in response to optical radiation that is incident on the device in a first band of wavelengths that is incident on the front side of the first die;
a second die, which has a first side fixedly aligned with the back side of the first die and is patterned to define a second array of second sensor elements configured to output second electrical signals in response to the optical radiation that is incident on the device in a second band of wavelengths, different from the first band, which passes through the first die and is incident on the first side of the second die;
an optical metasurface, which is disposed between the first and second dies and is configured to direct the optical radiation in the second band of wavelengths onto the second sensor elements; and
readout circuitry coupled to read the first electrical signals and the second electrical signals out of the device.

In a disclosed embodiment the optical metasurface is formed of two different materials having different refractive indices in the second band of wavelengths. A dimension of one of the materials may have a length that is shorter than a wavelength of the second band of wavelengths.

In a disclosed embodiment the optical further metasurface is fixed to the back side of the first die.

In a yet further disclosed embodiment the first die has a via layer formed on the back side of the first die, and the optical metasurface is formed within the via layer. The via layer may have a via formed of a via hole having an insulating dielectric liner deposited on a surface of the via hole.

In an alternative embodiment the first band consists of visible optical radiation, and the second band consists of infra-red radiation.

There is further provided, according to another embodiment of the present invention, a method for producing a sensing device, consisting of:
patterning a first die, which has a front side and a back side, to define a first array of first sensor elements configured to output first electrical signals in response to optical radiation that is incident on the device in a first band of wavelengths that is incident on the front side of the first die;
fixedly aligning a first side of a second die with the back side of the first die;
patterning the second die to define a second array of second sensor elements configured to output second electrical signals in response to the optical radiation that is incident on the device in a second band of wavelengths, different from the first band, which passes through the first die and is incident on the first side of the second die;
disposing an optical metasurface between the first and the second dies;
configuring the optical metasurface to direct the optical radiation in the second band of wavelengths onto the second sensor elements; and
coupling readout circuitry to read the first electrical signals and the second electrical signals out of the device.

The present disclosure will be more fully understood from the following detailed description of the embodiments thereof, taken together with the drawings, in which:

### BRIEF DESCRIPTION OF THE DRAWINGS

FIG. 1 illustrates a schematic cross-section of a portion of an image sensor, according to an embodiment of the present invention;

FIGS. 2A, 2B, and 2C schematically illustrate sections of surfaces of the image sensor, according to an embodiment of the present invention; and

FIG. 3 is a schematic illustration of the structure a via of the image sensor, according to an embodiment of the present invention.

### DETAILED DESCRIPTION OF EMBODIMENTS

### Overview

A stacked image sensor comprises a first array of visible light, i.e., red, green, blue (RGB) semiconducting sensors, stacked on a array of infra-red (IR) semiconducting sensors. Herein sensors are also referred to as pixels. In order for the stack to function, i.e., to detect visible and infra-red radiation, the RGB pixels must be transparent to the IR radiation impinging on the stack. Even so, the refraction and scattering of the IR radiation by the RGB pixels significantly reduces the efficiency of operation of the IR pixels, by reducing the IR radiation on a particular IR pixel, and by increasing the cross-talk between neighboring IR pixels. In addition, elements associated with the RGB pixels may be constructed from conductive material, which may absorb and/or reflect the IR radiation, further reducing the operational efficiency of the IR pixels.

Embodiments of the present invention overcome the problems described above by incorporating a metasurface between a lower surface of the RGB pixels and an upper surface of the IR pixels. The metasurface is formed from different materials transparent to the IR radiation, and the different materials are patterned to diffract and focus IR radiation passing through the RGB pixels to the IR pixels. The metasurface consequently increases the IR radiation falling on each of the IR pixels, and reduces the cross-talk between the IR pixels.

### DETAILED DESCRIPTION

In the following description, like elements in the drawings are identified by like numerals. In addition, all directional references (e. g., upper, lower, upward, downward, left, right, top, bottom, above, below, vertical, and horizontal) are only used for identification purposes to aid the reader's understanding of the present invention, and do not create limitations, particularly as to the position, orientation, or use of embodiments of the invention.

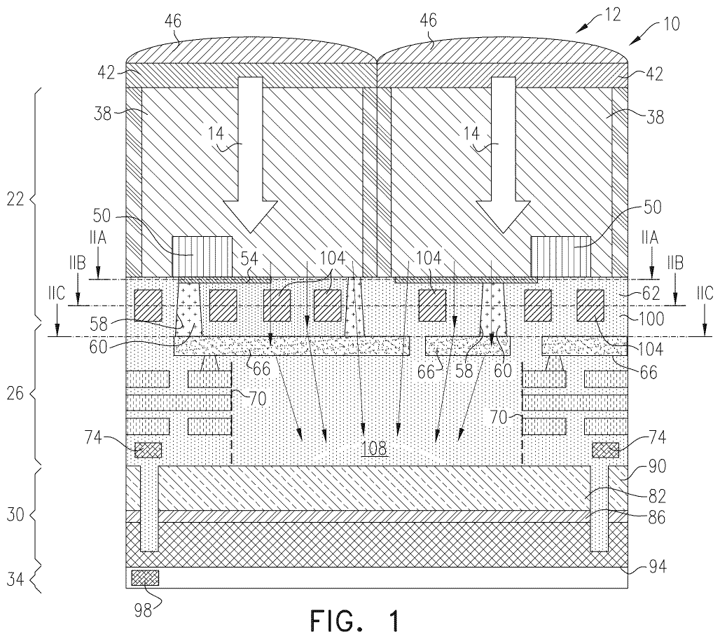

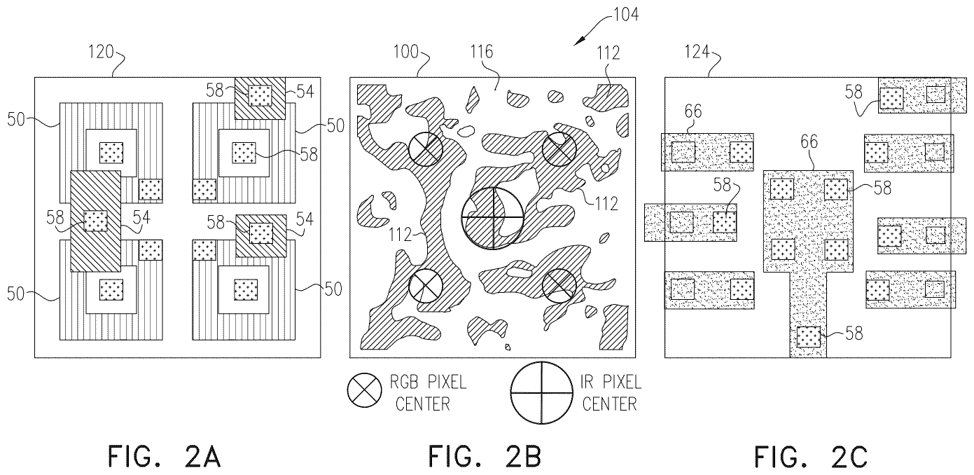

Reference is now made to FIG. 1 and to FIGS. 2A, 2B, and 2C. FIG. 1 schematically illustrates a cross-section of an image sensing device 10, herein also termed an image sensor 10, and FIGS. 2A, 2B, and 2C schematically illustrate sections o of surfaces of the image sensor, according to an embodiment of the present invention. FIGS. 2A, 2B, and 2C illustrate a metasurface and surfaces adjacent to the metasurface. For the sake of simplicity and clarity of illustration, the figures are only for a small portion 12 of the entire image sensor and are not drawn to scale.

In the following description, image sensor 10 is assumed to be receiving radiation travelling vertically downwards, so that FIG. 1 shows a vertical cross-section where the upper part of the figure corresponds to a top or front side of the sensor. The illustrations in FIGS. 2A, 2B, and 2C are horizontal planes of sensor 10, corresponding respectively to lines IIA-IIA, IIB-IIB, and IIC-IIC in FIG. 1.

Image sensor 10 is assumed to output first electrical signals in response to optical radiation that is incident on the sensor in a first band of wavelengths, and to output second electrical signals in response to the incident optical radiation in a second band of wavelengths, different from the first band. In the following description, for clarity and simplicity, the first band is assumed to comprise wavelengths less than 1000 nm, e.g., visible wavelengths, and the second band is assumed to comprise wavelengths greater than 1000 nm, e.g., infra-red (IR) wavelengths, and those having ordinary skill in the art will be able to adapt the description, mutatis mutandis, for other radiation bands. In the description the first band may also be referred to as visible radiation, and the second band as IR radiation.

In FIG. 1 paths of the visible radiation in sensor 10 are schematically illustrated by arrows 14, and paths of the IR radiation are schematically illustrated by arrows 18.

Image sensors such as sensor 10 are typically manufactured by stacking multiple patterned wafers, which are then diced to produce many image sensors of this type. In other words, each image sensor comprises a stack of subsidiary dies, derived from the stack of wafers, with intermediate metal and dielectric layers between the subsidiary dies.

In the embodiment described herein the stack of dies comprises a silicon die 22, having a front side and a back side which is bonded to the front side of a readout die 26. Readout die 26 at its back side is in turn bonded with the front side of an IR-sensing die 30. The back side of IR-sensing die 30 is bonded to another readout die 34. In the bonding, the front side of the IR-sensing die aligns with the back side of the silicon die.

The silicon die is patterned to define an array of sensor elements 38, also referred to herein as RGB (red, green, blue) pixels 38 and FIG. 1 illustrates two RGB pixels. The sensor elements output electrical signals in response to optical radiation in the first, visible, band of wavelengths that is incident on the top or front side of the silicon die. The sensor elements transmit the optical radiation in the second, IR, band of wavelengths.

As shown in FIG. 1, each RGB pixel may be overlain by a filter 42, typically a red, green or blue filter, and/or a microlens 46. The pixels are configured with photogates 50 and transistor gates 54, and in response to optical radiation in the first, visible, band of wavelengths, the photogates and the transistor gates generate electrical signals that are transferred by conductive vias 58 in a via layer 62. (Photogates 50, transistor gates 54, and vias 58 are also shown in FIG. 2A, which illustrates elements of pixels 38 in a layer above via layer 62, and which is described further below.) Each via 58 is formed of a via hole that, except as described otherwise herein, is completely filled with a conductive material 60.

In readout die 26, or alternatively in silicon die 22, local routing connections 66, formed from poly-silicon, connect to the vias, and, together with metal lines 70 in metal layers of the readout die, transfer the electrical signals to readout circuits 74 in the readout die. (Routing connections 66 and vias 58 are also shown in Fig, 2C, which illustrates elements of sensor 10 in a layer below via layer 62.) Typically, readout die 26 is made from a silicon wafer, and the readout circuits may be implemented in CMOS logic, as is known in the art. Alternatively, other implementations for the readout circuits may be used.

IR-sensing die 30 also comprises an array of sensor elements 82, also referred to herein as IR pixels 82, which output electrical signals in response to incident optical radiation in the second, IR, band of wavelengths. Each IR pixel 82 comprises a photosensitive material 86 that is sandwiched between a common electrode 90 and an IR pixel electrode 94. Photosensitive material 86 may comprise any suitable material with high quantum efficiency in the second band of wavelengths, such as organic photodiodes, a quantum film, or a semiconductor material.

Readout die 34 receives signals from IR pixel electrodes 94 and conveys the signals to a readout circuit 98. The data from readout circuit 98, as well as from the data from readout circuit 74 referred to above, simultaneously provide image data for the two spectral bands incident on sensor 10.

The RGB pixels are transparent to the optical radiation in the second, IR, band of wavelengths, and this band penetrates the pixels to a metasurface layer 100, which in a disclosed embodiment is formed on the lower surface of the RGB pixels of the silicon die by incorporation into via layer 62. Metasurface layer 100 comprises metasurface structures 104, which are schematically illustrated as squares in FIG. 1. Metasurface layer 100 is described further below.

Metasurface layer 100 receives the second, IR, band of wavelengths, and as is illustrated by arrows 18 in FIG. 1, the metasurface is configured to focus the IR radiation to the top surface of IR sensing die 30, i.e., to the top surface of IR pixel 82. The focused IR radiation is transmitted to the top surface of the IR pixel through intervening metal layers of readout die 26, and in an embodiment metal lines 70 in the metal layers have been positioned to provide a routing window 108, through the layers, for the IR radiation to the IR pixel.

FIG. 2B, which corresponds to line IIB-IIB of FIG. 1, illustrates metasurface layer 100 for portion 12. The centers of four RGB pixels 38, and the center of IR pixel 82, as viewed from above the metasurface, have been marked on the illustration of the metasurface. The metasurface is formed from two different materials that are transparent to the second, IR, band of wavelengths, and that also have different refractive indices in this band. For simplicity, vias 58 penetrating the metasurface are not shown in the figure. When sensor 10 is produced, the vias should be electrically isolated from each other. Alternatively or additionally, parts of the metasurface may be configured to be electrically conductive to serve the function of the vias.

In the embodiment of metasurface layer 100 illustrated in FIG. 2B, the two different materials of the metasurface, corresponding to metasurface structures 104 referred to above, comprise polysilicon 112 and silicon dioxide (SiO₂) 116. These materials are patterned to diffract and focus the second band of radiation to a respective IR pixel 82 a s aligned with a set of RGB pixels 38. Thus, in the illustrated embodiment, the metasurface diffracts and focuses the second band of radiation to the IR pixel centered beneath the four RGB pixels. It will be understood that in order to achieve the required diffraction and focusing effects, at least some dimensions of the materials of the metasurface comprise lengths shorter than the wavelengths of the second band of radiation.

FIG. 2A, which corresponds to line IIA-IIA, is derived from a mask 120 for elements of sensor 10 above metasurface 100. The figure illustrates vias 58, photogates 50, and transistor gates 54 as seen from above the metasurface.

FIG. 2C, which corresponds to line IIC-IIC, is derived from a mask 124 for elements of sensor 10 below metasurface 100. The figure illustrates vias 58, and connections 66 as seen from below the metasurface.

In a disclosed embodiment RGB pixels 38 have a separation of 1 μm, and the square frames of FIGS. 2A, 2B, and 2C, respectively illustrating a layer above the metasurface, the metasurface, and a layer below the metasurface, have sides of length 2 μm. However, it will be understood that the dimensions and arrangement of the stacked dies illustrated in the figures are by way of example, and other suitable arrangements of the RGB pixels and IR pixels will be apparent to those of ordinary skill in the art. For example, one IR pixel may be centered on a square of 4×4 RGB pixels, each of the RGB pixels being separated, as in the illustrated example, by 1 μm. Thus, all such arrangements are assumed to be comprised within the scope of the present invention.

As explained above, vias 58 are illustrated as connecting transistor gates 54 to local routing connections 66 and the vias are completely filled with conductive material 60 to convey signals between the gates and the connections.

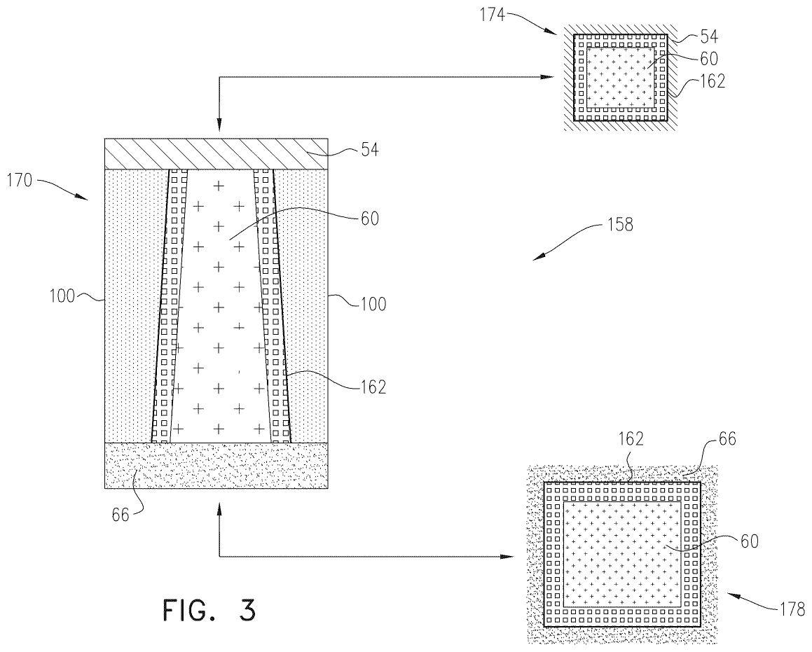

FIG. 3 schematically illustrates an alternative via 158, according to an embodiment of the present invention. The figure shows a section 170 of the alternative via as it would be seen in FIG. 1, a view 174 of the alternative via from above, as it would be seen in FIG. 2A, and a view 178 of the alternative via from below, as it would be seen in FIG. 2C. The alternative via is assumed to be formed within metasurface layer 100 and apart from the differences described below, the operation of via 158 is generally similar to that of a via 58 that electrically connects a transistor gate 54 to a local routing connection 66. Thus, in the embodiment described herein, alternative via 158 also electrically connects a transistor gate 54 to a connection 66.

In contrast to via 58 wherein the via hole of the via is completely filled with conductive material 60, in via 158 the via hole is not completely filled with conductive material. Rather, a thin insulating dielectric layer 162, also referred to herein as liner 162, is deposited on the inside surfaces of the via hole, and the remaining space within the via is filled with conductive material 60. As is apparent from FIG. 3, liner 162 serves to electrically isolate the metasurface from conductive material 60, and thus from electrical layers of sensor 10 connected to the conductive material.

In a disclosed embodiment the liner is made from silicon dioxide and/or silicon nitride, and the liner thickness is in the range of 5 nm-10 nm. However, other embodiments may have a thickness outside this range.

Providing an insulating liner ensures that there is no electrical leakage between vias through adjoining metasurface material, and reduces the space needed between adjacent vias. In addition, the liner acts as a diffusion barrier.

Although the use of an insulating dielectric oxide or nitride layer between the metasurface and underlying electrical layers is described here in the specific context of our stacked die image sensor, this sort of dielectric layer will also be useful in other sorts of optoelectronic devices that combine metasurfaces and electrical circuits.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A multispectral sensing device, comprising:
a first die, which has a front side and a back side and is patterned to define a first array of first sensor elements configured to output first electrical signals in response to optical radiation that is incident on the device in a first band of wavelengths that is incident on the front side of the first die;
a second die, which has a first side fixedly aligned with the back side of the first die and is patterned to define a second array of second sensor elements configured to output second electrical signals in response to the optical radiation that is incident on the device in a second band of wavelengths, different from the first band, which passes through the first die and is incident on the first side of the second die;
an optical metasurface, which is disposed between the first and second dies and is configured to direct the optical radiation in the second band of wavelengths onto the second sensor elements; and
readout circuitry coupled to read the first electrical signals and the second electrical signals out of the device.

2. The device according to claim 1, wherein the optical metasurface comprises two different materials having different refractive indices second band of wavelengths.

3. The device according to claim 2, wherein a dimension of one of the materials comprises a length that is shorter than a wavelength of the second band of wavelengths.

4. The device according to claim 1, wherein the optical metasurface is fixed to the back side of the first die.

5. The device according to claim 1, wherein the first die comprises a via layer formed on the back side of the first die, and wherein the optical metasurface is formed within the via layer.

6. The device according to claim 5, wherein the via layer comprises a via formed of a via hole having an insulating dielectric liner deposited on a surface of the via hole.

7. The device according to claim 1, wherein the first band comprises visible optical radiation, and the second band comprises infra-red radiation.

8. A method for producing a sensing device, comprising:
patterning a first die, which has a front side and a back side, to define a first array of first sensor elements configured to output first electrical signals in response to optical radiation that is incident on the device in a first band of wavelengths that is incident on the front side of the first die;
fixedly aligning a first side of a second die with the back side of the first die;
patterning the second die to define a second array of second sensor elements configured to second electrical signals in response to the optical radiation that is incident on the device in a second band of wavelengths, different from the first band, which passes through the first die and is incident on the first side of the second die;
disposing an optical metasurface between the first and the second dies;
configuring the optical metasurface to direct the optical radiation in the second band of wavelengths onto the second sensor elements; and
coupling readout circuitry to read the first electrical signals and the second electrical signals out of the device.

9. The method according to claim 8, wherein the optical metasurface comprises two different materials having different refractive indices in the second band of wavelengths.

10. The method according to claim 9, wherein a dimension of one of the materials comprises a length that is shorter than a wavelength of the second band of wavelengths.

11. The method according to claim 8, wherein the optical metasurface is fixed to the back side of the first die.

12. The method according to claim 8, wherein the first die comprises a via layer formed on the back side of the first die, and wherein the optical metasurface is formed within the via layer.

13. The method according to claim 12, wherein the via layer comprises a via formed of a via hole having an insulating dielectric liner deposited on a surface of the via hole.

14. The method according to claim 8, wherein the first band comprises visible optical radiation, and the second band comprises infra-red radiation.
